(19) United States
(12) Patent Application Publication
(10) Pub. No.: US 2026/0090377 A1
(43) Pub. Date: Mar. 26, 2026

(54) INTEGRATED CIRCUIT PACKAGE CAPABLE OF INDEPENDENTLY ASSEMBLING PASSIVE DEVICE AND MANUFACTURING METHOD THEREOF

(71) Applicant: Richtek Technology Corporation, Hsinchu (TW)

(72) Inventors: Shih-Chieh LIN, Kaohsiung (TW); Heng-Chi HUANG, Hsinchu (TW)

(21) Appl. No.: 19/182,582

(22) Filed: Apr. 17, 2025

Related U.S. Application Data
(60) Provisional application No. 63/697,581, filed on Sep. 22, 2024.

(30) Foreign Application Priority Data
Jan. 15, 2025 (TW) 114101716

(51) Int. Cl. H01L 23/367; H01L 21/48; H01L 21/50; H01L 23/00; H01L 23/373; H01L 25/18; H10D 1/20

(52) U.S. Cl. CPC H10W 40/226; H10W 40/037; H10W 40/258; H10W 40/259; H10W 90/00; H10W 95/00; H10D 1/20; H10W 90/736

(57) ABSTRACT

The present invention provides an integrated circuit package capable of independently assembling passive devices and a manufacturing method thereof. The integrated circuit package includes: an integrated circuit configured to be mounted on a circuit board; and a heat dissipation structure, which is manufactured independently and has a first-layer flat plate disposed above the integrated circuit and in thermal contact therewith, and a cavity located on one side of the first-layer flat plate. The cavity is formed with at least one opening to accommodate a passive device. During assembly, the passive device is inserted into the cavity of the heat dissipation structure through the at least one opening and is electrically connected to the circuit board or the integrated circuit via an electrical conductor of the passive device. Heat generated by the integrated circuit is transferred through the heat dissipation structure.

### CROSS REFERENCE

The present invention claims priority to U.S. 63/697581 filed on Sep. 22, 2024, and claims priority to TW 114101716 filed on Jan. 15, 2025.

### BACKGROUND OF THE INVENTION

### Field of Invention

The present invention relates to an integrated circuit package capable of independently assembling passive devices and a manufacturing method thereof, and more particularly to such an integrated circuit package in which the heat dissipation structure is manufactured independently and the passive device can be assembled independently.

### Description of Related Art

As shown in FIG. 1, U.S. Pat. No. 11,770,916 discloses an inductor structure 1, in which an outer portion of an inductor is covered by a metal strip 3 made of a high thermal conductivity material. The metal strip 3 is intended to enhance heat conduction between the inductor and an integrated circuit chip, thereby improving heat dissipation efficiency. The metal strip 3 can be made of high thermal conductivity materials such as copper, silver, or aluminum. The width of the metal strip 3 may be adjusted as needed to ensure effective thermal connection with the underlying integrated circuit chip.

However, the prior art exhibits several apparent drawbacks. First, the metal strip 3 is installed by wrapping it around the inductor after the inductor is manufactured. Since the metal strip 3 must be precisely bent to match the shape of the inductor, it is difficult to ensure perfect contact between the metal strip 3 and the surface of the inductor during manufacturing. In particular, achieving accurate 90-degree bends is difficult, resulting in uneven or excessively large gaps between the metal strip 3 and the inductor, which adversely affects heat conduction efficiency.

Second, a thermal interface material (TIM) is required between the metal strip 3 and the inductor to ensure thermal connection. Since the thermal conductivity of TIM is relatively low (typically 1 to 2 W/m·K), and gaps exist at the starting and ending points of the metal strip 3, the thermal resistance is further increased, thereby degrading the overall heat transfer efficiency. In addition, because the metal strip 3 mainly surrounds the side surfaces of the inductor, the heat must travel along a longer path, increasing the thermal resistance from the integrated circuit chip to the heat sink, and thus reducing the overall heat dissipation performance.

Furthermore, when switching to a different inductor supplier or a different inductor size or specification, it is often necessary to redevelop or customize a new metal strip 3, resulting in a lack of manufacturing flexibility, increased process complexity, and higher costs.

In view of the drawbacks of the prior art, the present invention provides a novel design of an integrated circuit package capable of independently assembling passive devices. Through a simplified manufacturing process, the invention significantly enhances heat dissipation performance and manufacturing flexibility.

### SUMMARY OF THE INVENTION

From one perspective, the present invention provides an integrated circuit package capable of independently assembling passive devices. The integrated circuit package includes: an integrated circuit configured to be mounted on a circuit board; and a heat dissipation structure, which is manufactured independently and includes: a first-layer flat plate disposed above the integrated circuit and in thermal contact therewith; and a cavity located on one side of the first-layer flat plate. The cavity has at least one opening for accommodating a passive device. During assembly, the passive device is inserted into the cavity through the opening of the heat dissipation structure and is electrically connected to the circuit board or the integrated circuit via an electrical conductor of the passive device. Heat generated by the integrated circuit is transferred through the heat dissipation structure.

In another aspect, the present invention provides a method of manufacturing an integrated circuit package capable of independently assembling passive devices. The method includes: mounting an integrated circuit on a circuit board; independently pre-fabricating a heat dissipation structure, the heat dissipation structure comprising a first-layer flat plate and a cavity, wherein the cavity is located on one side of the first-layer flat plate and has at least one opening; installing the heat dissipation structure above the integrated circuit such that the first-layer flat plate is in thermal contact with the integrated circuit; inserting at least one passive device into the cavity through the at least one opening; and electrically connecting the passive device to the circuit board or the integrated circuit via an electrical conductor thereof.

In one embodiment, the passive device includes an inductor.

In one embodiment, the heat dissipation structure is made of a formable metal, such as steel, copper, silver, gold, aluminum, tungsten, zinc, or stainless steel.

In one embodiment, the heat dissipation structure is formed by a process selected from casting, milling, turning, stamping, or forging.

In one embodiment, the heat dissipation structure is made of a non-metallic material, such as aluminum nitride, silicon carbide, or graphite.

In one embodiment, the first-layer flat plate is bonded to a top surface of the integrated circuit via a thermal interface material.

In one embodiment, the passive device is optionally inserted into the cavity through the at least one opening or removed therefrom through the same.

In one embodiment, an upper surface of the passive device is flush or substantially flush with a top surface of the heat dissipation structure, such that the passive device and the heat dissipation structure are simultaneously in thermal contact with an external heat sink.

In one embodiment, the heat dissipation structure further comprises the first-layer flat plate and at least one second-layer flat plate, interconnected by one or more metal pillars, such that multiple passive devices are layered and stacked on the first-layer and second-layer flat plates, for accommodating multiple passive devices or enhancing heat dissipation efficiency.

In one embodiment, the passive device is further connected to the circuit board via a thermal conduction pillar, which is made of a formable metal such as copper, silver, gold, or aluminum.

Compared to the prior art, the present invention offers significant advantages. First, since the heat dissipation structure of the present invention is independently manufactured and retains a gap for accommodating inductors of various brands or standard sizes, there is no need to redesign the entire heat dissipating metal part when replacing an inductor, thereby simplifying the development process for different inductor designs and electrical specifications.

Second, the heat dissipation structure can be designed as a flat or multi-layer extended metal component that adheres to the top surface of the integrated circuit (IC), thereby effectively channeling the heat generated by the IC to external heat dissipation paths (e.g., a heat sink or housing structure).

Furthermore, if the inductor also generates heat, the heat dissipation structure of the present invention can simultaneously contact the top or side surfaces of the inductor to further conduct the heat away. Alternatively, thermal interface materials (such as TIM or solder) can be applied to compensate for tolerances and improve thermal transfer efficiency.

Additionally, the heat dissipation structure of the present invention may be of a single-layer, double-layer, or extended form in both directions, and may even accommodate second-layer or third-layer stacked passive devices.

In summary, the present invention overcomes deficiencies in the prior art related to manufacturing complexity, heat conduction paths, thermal resistance, and heat dissipation performance. Through an innovative structural design and manufacturing process, the present invention provides a more effective heat dissipation solution, manufacturing process, and flexibility. It is particularly suitable for electronic components with high power density and high heat generation, thereby enhancing the reliability and performance of the device.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a schematic diagram illustrating an inductor structure disclosed in U.S. Pat. No. 11,770,916 as prior art.

FIGS. 2A and 2B are front and side cross-sectional views, respectively, illustrating an embodiment of an integrated circuit package capable of independently assembling passive devices in accordance with the present invention.

FIGS. 3A, 3B, and 3C are a front cross-sectional view, a side cross-sectional view, and a perspective view, respectively, illustrating another embodiment of the integrated circuit package 20 in accordance with the present invention.

FIG. 4 is a front cross-sectional view illustrating another embodiment of the integrated circuit package 30 in accordance with the present invention.

FIG. 5 is a front cross-sectional view illustrating another embodiment of the integrated circuit package 40 in accordance with the present invention.

FIG. 6 is a front cross-sectional view illustrating another embodiment of the integrated circuit package 50 in accordance with the present invention.

FIGS. 7A and 7B are front and side cross-sectional views, respectively, illustrating an embodiment of the integrated circuit package 60 in accordance with the present invention.

FIGS. 8A and 8B are front and side cross-sectional views, respectively, illustrating another embodiment of the integrated circuit package 70 in accordance with the present invention.

FIGS. 9A and 9B are front and side cross-sectional views, respectively, illustrating an embodiment of the integrated circuit package 80 in accordance with the present invention.

FIGS. 10A and 10B are front and side cross-sectional views, respectively, illustrating an embodiment of the integrated circuit package 90 in accordance with the present invention.

FIG. 11 is a cross-sectional view illustrating an embodiment of the integrated circuit package 100 in accordance with the present invention.

FIG. 12 is a cross-sectional view illustrating an embodiment of the integrated circuit package 110 in accordance with the present invention.

FIG. 13 is a cross-sectional view illustrating an embodiment of the integrated circuit package 120 in accordance with the present invention.

FIG. 14 is a cross-sectional view illustrating an embodiment of the integrated circuit package 130 in accordance with the present invention.

FIGS. 15A, 15C, 15E, and 15G are cross-sectional views illustrating different steps in a manufacturing process of the integrated circuit package 20 in accordance with the present invention. FIGS. 15B, 15D, 15F, and 15H are perspective views respectively corresponding to FIGS. 15A, 15C, 15E, and 15G.

FIGS. 16A to 16H are cross-sectional views illustrating different steps in another manufacturing process of the integrated circuit package 20 in accordance with the present invention.

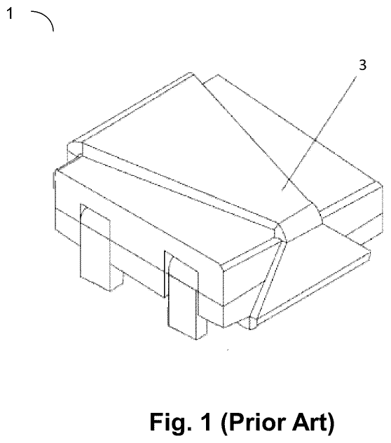

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

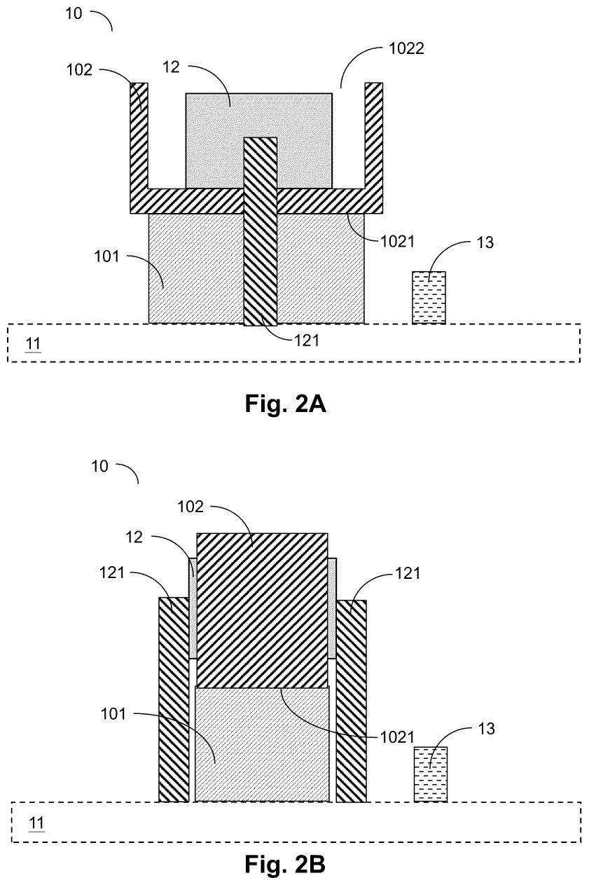

FIGS. 2A and 2B are schematic front and side cross-sectional views, respectively, of an embodiment of an integrated circuit package capable of independently assembling passive devices according to the present invention. As shown in FIG. 2A, the integrated circuit package 10 includes an integrated circuit 101 and a heat dissipation structure 102. The integrated circuit 101 is configured to be mounted on a circuit board 11. The heat dissipation structure 102 is independently manufactured and includes a first-layer flat plate 1021 and a cavity 1022. The first-layer flat plate 1021 is disposed over the integrated circuit 101 and in thermal contact therewith. The cavity 1022 is located on a side of the first-layer flat plate 1021 opposite to the integrated circuit 101, and is formed with at least one opening for accommodating a passive device 12.

Note that, the phrase “capable of independently assembling passive devices” indicates that the structure of the integrated circuit package is designed in such a way that the passive devices (e.g., inductors, capacitors, or other components not actively switching) can be individually installed, removed, or replaced without modifying the overall layout or structure of the package. This modular design allows for flexibility in manufacturing and maintenance processes, such as selecting from different passive device suppliers, updating component specifications, or performing post-assembly customization or repair.

Additionally, the phrase “heat dissipation structure is manufactured independently” indicates that the heat dissipation structure is fabricated as a separate component prior to being attached to the integrated circuit. In other words, the heat dissipation structure is not formed integrally with the integrated circuit or substrate during the same fabrication process. Instead, it is prefabricated and subsequently mounted onto the integrated circuit, thereby allowing greater flexibility in selecting materials, processes, or geometries suited for thermal management.

As further illustrated in FIG. 2A, the cavity 1022 of the integrated circuit package 10 has an opening providing space for assembling the passive device 12. During the assembly process, the passive device 12 is inserted into the cavity 1022 through the opening and is mounted atop the first-layer flat plate 1021. An electrical conductor 121 of the passive device 12 extends to the circuit board 11 to complete electrical connection thereto. Optionally, the electrical conductor 121 may also be electrically connected directly to an electrical terminal of the integrated circuit 101.

Referring to FIG. 2B, the first-layer flat plate 1021 of the heat dissipation structure 102 is in direct contact with the top surface of the integrated circuit 101 to absorb the heat generated thereby. The heat is conducted through the metal material of the heat dissipation structure 102 to the cavity 1022 and further dissipated through thermal contact with the passive device 12. This design not only enhances thermal performance but also simplifies the replacement process of the passive device 12, satisfying various application demands on the inductance parameters.

In addition, FIGS. 2A and 2B show another electronic component 13, which may optionally be mounted on the circuit board 11 and electrically or mechanically coupled to the integrated circuit 101 or the passive device 12. This modular design allows flexible configuration of different components according to application needs, thereby enhancing the applicability and functional flexibility of the integrated circuit package.

In one embodiment, the passive device 12 includes an inductor.

In one embodiment, the heat dissipation structure 102 is made of a formable metal, including but not limited to steel, copper, silver, gold, aluminum, tungsten, zinc, or stainless steel. Note that, the term “formable metal” indicates that the metal material is capable of being shaped, processed, or manufactured by conventional fabrication techniques, including but not limited to casting, milling, turning, stamping, or forging. The formable metal may include, for example, steel, copper, silver, gold, aluminum, tungsten, zinc, stainless steel, or other metals having sufficient mechanical properties for thermal conduction and structural integrity in electronic packaging applications.

In one embodiment, the heat dissipation structure 102 is formed by a process selected from casting, milling, turning, stamping, or forging.

In another embodiment, the heat dissipation structure 102 is made of a non-metallic material, such as aluminum nitride, silicon carbide, or graphite.

In one embodiment, the first-layer flat plate 1021 is adhered to the top surface of the integrated circuit 101 through a thermal interface material (TIM).

In one embodiment, the passive device 12 is optionally inserted into the cavity 1022 through the at least one opening, or removed therefrom.

It is to be noted that the thermal interface material (TIM) is a commonly used substance in electronic devices, primarily used to fill the gaps between heat-generating components and heat dissipation structures. Due to the unevenness of contact surfaces between components such as integrated circuits or power semiconductor devices and heat sinks, air gaps often exist, which degrade heat conduction. TIMs are used to fill these gaps and reduce thermal resistance, thereby enhancing the transfer of heat. Common TIMs include thermal adhesives, thermal pads, thermal tapes, thermal gels, phase change materials, and metal-based thermal interface materials, with typical thermal conductivities ranging from 1 to 2 W/m·K.

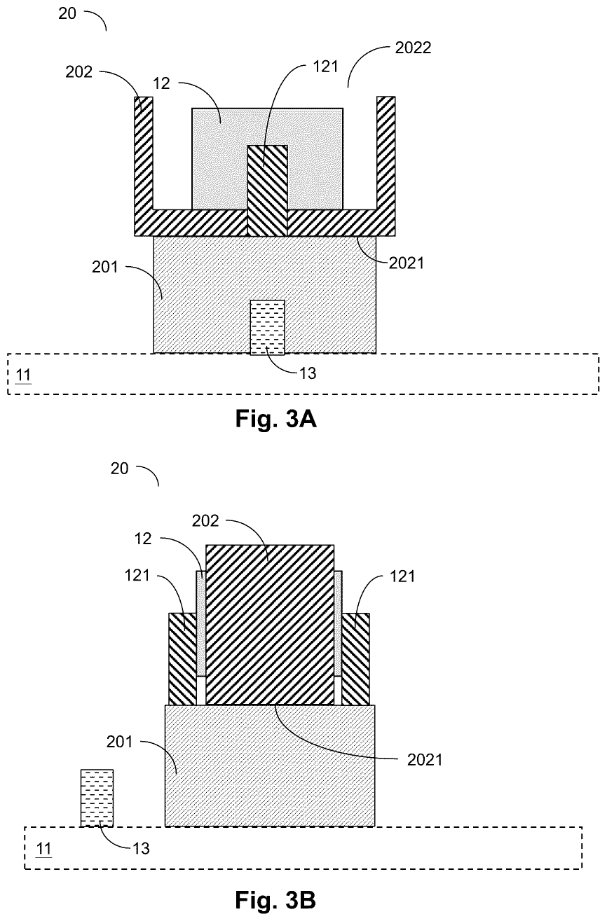

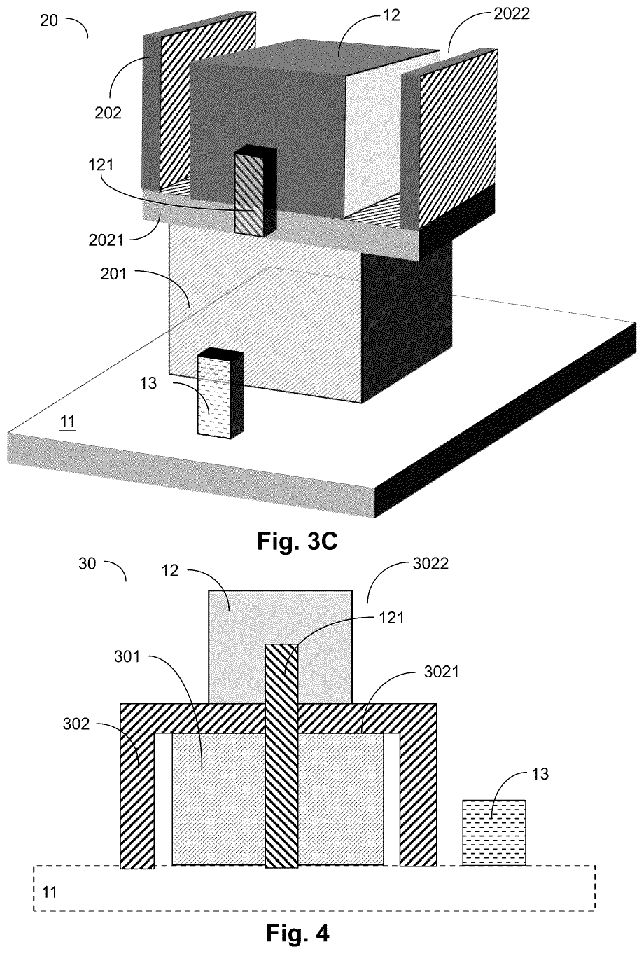

FIGS. 3A, 3B, and 3C respectively illustrate a front cross-sectional view, a side cross-sectional view, and a perspective view of another embodiment of the integrated circuit package capable of independently assembling passive devices according to the present invention.

As shown in FIG. 3A, the integrated circuit package 20 capable of independently assembling passive devices includes an integrated circuit 201 and a heat dissipation structure 202. The integrated circuit 201 is configured to be mounted on a circuit board 11 and generates electrical signals and heat energy.

The heat dissipation structure 202 is manufactured independently and includes a first-layer flat plate 2021 and a cavity 2022. The first-layer flat plate 2021 is disposed on a top surface of the integrated circuit 201 and is in thermal contact with the integrated circuit 201 through a thermal interface material (not shown in the figure). The cavity 2022 is located on the opposite side of the first-layer flat plate 2021 and includes at least one opening to accommodate a passive device 12.

As shown in FIG. 3B, an electrical conductor 121 of the passive device 12 extends to the integrated circuit 201, thereby establishing an electrical connection. This design enables the passive device 12 to effectively transmit both heat and electrical signals while the electrical conductor 121 is in contact with the integrated circuit 201. Furthermore, the cavity 2022 is configured to accommodate passive devices 12 of various specifications, thereby providing high assembly flexibility.

As shown in FIG. 3C, the perspective view of the integrated circuit package 20 clearly illustrates the spatial relationship between the heat dissipation structure 202 and the integrated circuit 201. The first-layer flat plate 2021 of the heat dissipation structure 202 provides a broad and stable thermal contact area, ensuring that the heat generated by the integrated circuit 201 is effectively guided toward the surrounding structure of the cavity 2022 and eventually dissipated via an external heat sink (not shown in the figure).

Additionally, as shown in FIG. 3C, an electronic component 13 may optionally be mounted on the circuit board 11 and electrically connected to the integrated circuit 201 or the passive device 12. The modularized design further enhances the system's flexibility and applicability.

The design features of the above embodiment include: first, the independently manufactured heat dissipation structure 202 with the cavity 2022 is adaptable to various specifications of passive devices; second, the first-layer flat plate 2021 is in thermal contact with the integrated circuit 201 via the thermal interface material to enhance thermal dissipation efficiency; third, the electrical conductor 121 of the passive device 12 is electrically connected to the integrated circuit 201, providing reliable electrical performance; fourth, the modular structure design allows multi-layer assembly or component replacement to meet different application requirements.

FIG. 4 illustrates a front cross-sectional view of another embodiment of the integrated circuit package 30 capable of independently assembling passive devices according to the present invention. As shown in FIG. 4, the integrated circuit package 30 includes an integrated circuit 301 and a heat dissipation structure 302. The integrated circuit 301 is mounted on the circuit board 11 and is electrically connected thereto.

The heat dissipation structure 302 is manufactured independently and includes a first-layer flat plate 3021 and a cavity 3022. The first-layer flat plate 3021 is disposed above the integrated circuit 301 and is in close thermal contact with the top surface of the integrated circuit 301 through a thermal interface material (not shown in the figure) for efficient heat conduction. The cavity 3022 is located above the first-layer flat plate 3021 and forms a space configured to accommodate a passive device 12. The cavity 3022 has at least one opening that allows the passive device 12 to be inserted into or removed from the cavity 3022.

An electrical conductor 121 of the passive device 12 passes through a side of the first-layer flat plate 3021 of the heat dissipation structure 302 and extends to the circuit board 11, thereby establishing an electrical connection with the circuit board 11.

The heat dissipation structure 302 in this embodiment differs from the heat dissipation structure 202 in that the cavity above the first-layer flat plate 3021 is fully open, lacking additional structures as in 202, and is thus more adaptable to passive devices 12 of different specifications. The size and shape of the first-layer flat plate 3021 of the heat dissipation structure 302 can be adjusted according to application needs to accommodate a variety of passive device models such as inductors, capacitors, or other electronic components. Furthermore, the design of the cavity 3022 better supports insertion and removal operations of the passive device 12, providing ease of maintenance and replacement. Since the heat dissipation structure 302 is connected to the circuit board 11, the heat generated by the integrated circuit 301 can be transmitted via more conduction paths to the circuit board 11, thereby achieving improved heat dissipation.

As shown in FIG. 4, an electronic component 13 may optionally be disposed on the circuit board 11 in addition to the integrated circuit 301 and the passive device 12, and may operate in conjunction with either of them. The layout of the electronic component 13, when combined with the modular design of the heat dissipation structure 302, further enhances the flexibility of the overall package structure in terms of functional design.

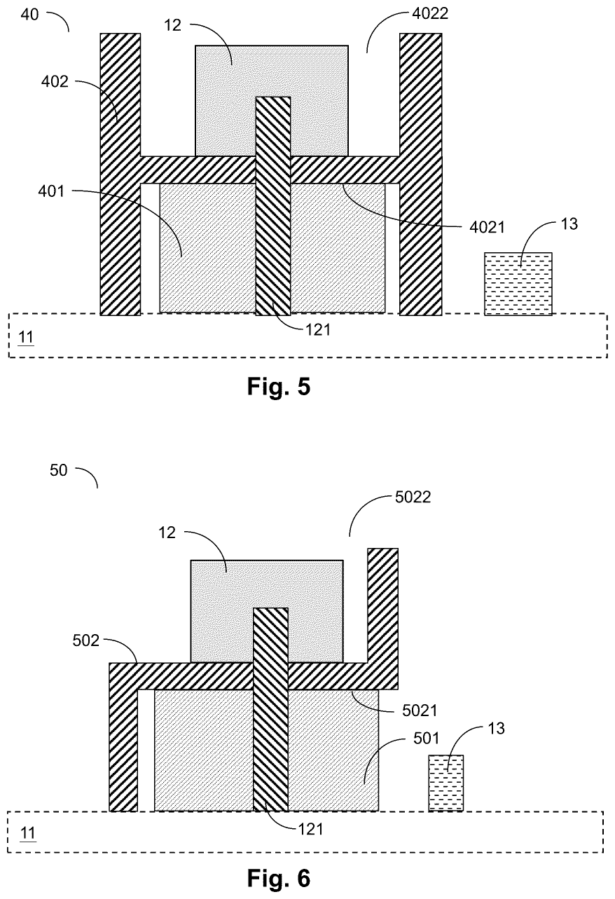

As shown in FIG. 5, the integrated circuit package 40, which is configured to independently accommodate passive devices, includes an integrated circuit 401 and a heat dissipation structure 402. The integrated circuit 401 is mounted on the circuit board 11 and is electrically connected thereto.

The heat dissipation structure 402 is manufactured independently and includes a first-layer flat plate 4021 and a cavity 4022. The first-layer flat plate 4021 is disposed above the top surface of the integrated circuit 401 and is in close thermal contact therewith through a layer of thermal interface material (not shown in the figure), so as to effectively conduct heat. The cavity 4022 is disposed above the first-layer flat plate 4021 and is configured to accommodate a passive device 12. The cavity 4022 has at least one opening which allows the passive device 12 to be inserted into or removed from the cavity 4022, thereby achieving greater flexibility in assembly and maintenance.

An electrical conductor 121 of the passive device 12 passes through the side edge of the first-layer flat plate 4021 of the heat dissipation structure 402 and extends to the circuit board 11, thereby establishing an electrical connection with the circuit board 11. This design ensures stable electrical performance and enables thermal energy generated by the passive device 12 to be dissipated through the upper surface of the heat dissipation structure 402, thereby achieving efficient heat dissipation.

As further shown in FIG. 5, the heat dissipation structure 402 is in contact with the circuit board 11, thereby forming an additional thermal conduction path. When the integrated circuit 401 generates heat, the heat can be conducted not only upward through the first-layer flat plate 4021 to the cavity 4022, but also directly propagated to the circuit board 11 through the heat dissipation structure 402. This design significantly enhances heat dispersion and heat dissipation, thereby improving the stability and service life of the integrated circuit package 40.

The modular design of this embodiment further enhances the application flexibility and universality of the heat dissipation structure 402. The shape and dimensions of the cavity 4022 can be adjusted according to application requirements to accommodate passive devices 12 of various specifications, such as inductors or capacitors. Additionally, the detachability of the cavity 4022 allows users to flexibly replace passive devices 12 as needed, further improving maintenance efficiency.

As shown in FIG. 6, the integrated circuit package 50 capable of independently assembling passive devices includes an integrated circuit 501 and a heat dissipation structure 502. The integrated circuit 501 is mounted on a circuit board 11 and electrically connected thereto.

The heat dissipation structure 502 is independently manufactured and includes a first-layer flat plate 5021 and a cavity 5022. The first-layer flat plate 5021 is disposed above the integrated circuit 501 and is in thermal contact therewith through a thermal interface material (not shown in the figure). The cavity 5022 is located above the first-layer flat plate 5021 and has at least one opening for accommodating a passive device 12. This design allows the passive device 12 to be inserted into or removed from the cavity 5022 through the opening, to meet different application requirements.

An electrical conductor 121 of the passive device 12 passes through the side edge of the first-layer flat plate 5021 of the heat dissipation structure 502 and extends to the circuit board 11 to achieve electrical connection therewith.

The design of the heat dissipation structure 502 enhances the thermal conduction capability of the overall package. When the integrated circuit 501 generates heat, the heat is transferred upward through the first-layer flat plate 5021 to the passive device 12 and the surroundings of the cavity 5022, and can also be dissipated outward through the sidewalls of the heat dissipation structure 502 to the external environment. Additionally, the direct contact between the heat dissipation structure 502 and the circuit board 11 provides an additional thermal conduction path, effectively improving the heat dissipation efficiency and ensuring stable operation of the system.

The modular design in this embodiment allows the heat dissipation structure 502 to be adjusted according to application requirements, so as to accommodate passive devices 12 of different sizes and specifications. The opening design of the cavity 5022 also supports quick replacement and maintenance of the passive device 12, further enhancing the flexibility and convenience of the system.

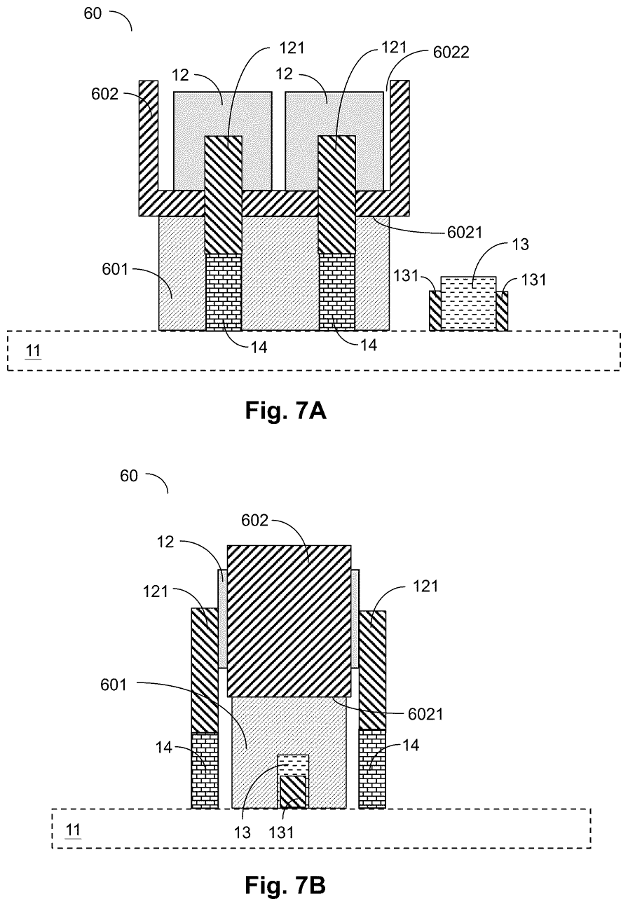

FIGS. 7A and 7B respectively illustrate front and side cross-sectional schematic views of an embodiment of an integrated circuit package 60 capable of independently assembling passive devices according to the present invention. As shown in FIGS. 7A and 7B, the integrated circuit package 60 includes an integrated circuit 601 and a heat dissipation structure 602. The integrated circuit 601 is mounted on a circuit board 11.

The heat dissipation structure 602 is independently manufactured and includes a first-layer flat plate 6021 and a cavity 6022. The first-layer flat plate 6021 is disposed above the integrated circuit 601 and is in thermal contact with the top surface of the integrated circuit 601 through a thermal interface material (not shown in the figure). The cavity 6022 is located above the first-layer flat plate 6021 and accommodates a plurality of passive devices 12. It has at least one opening that allows the passive devices 12 to be inserted into or removed from the cavity to achieve enhanced assembly flexibility.

The passive device 12 includes an electrical conductor 121, which extends externally along the side of the first-layer flat plate of the heat dissipation structure 602 and connects to a thermal conductor column 14, which in turn extends to the circuit board 11 to complete the electrical connection. The top surface of the passive device 12 is substantially flush with the top surface of the heat dissipation structure 602, allowing the passive device 12 to come into contact with an external heat sink (not shown in the figure), further enhancing the heat dissipation efficiency.

The thermal conductor column 14 is disposed between the passive device 12 and the circuit board 11. It is made of a high thermal conductivity metal, such as copper, silver, gold, or aluminum, and is used not only to electrically and mechanically connect the passive device 12 and the circuit board 11, but also to form an additional thermal conduction path from the integrated circuit 601 through the circuit board 11 to the passive device 12 and the heat dissipation structure 602, thereby significantly improving heat dissipation efficiency. Furthermore, the modular design of the thermal conductor column 14 allows adjustment of its quantity and layout according to the height requirements of the passive device 12, providing a flexible electrical, mechanical, and thermal connection solution.

An electronic component 13 is mounted on the circuit board 11 and electrically connected thereto through an electrical conductor 131.

Compared to other embodiments, the features of the embodiment shown in FIGS. 7A and 7B include: first, the modular design of the heat dissipation structure 602 allows for the insertion and removal of multiple passive devices 12; second, the provision of the thermal conductor column 14 offers a flexible solution for electrical, mechanical, and thermal connection.

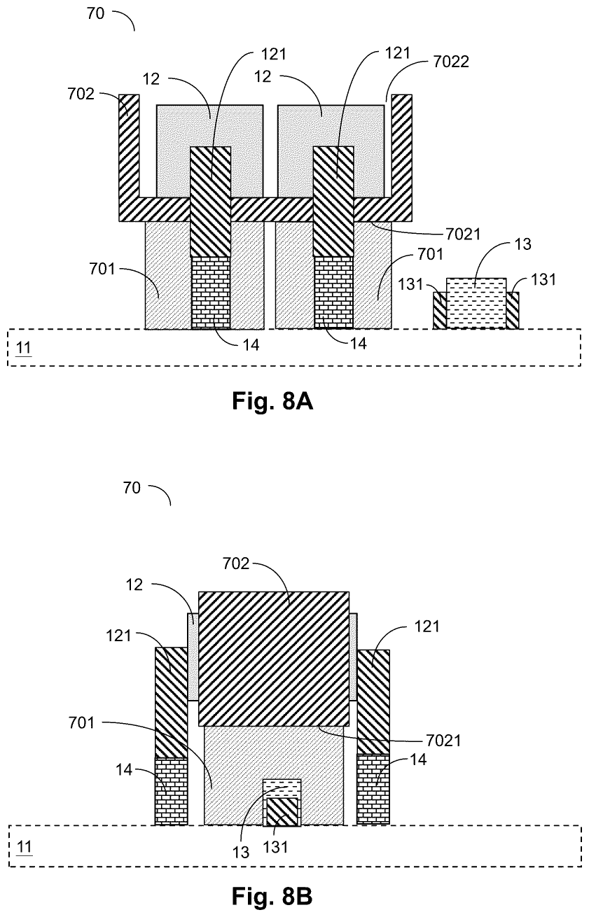

FIGS. 8A and 8B respectively illustrate a front cross-sectional view and a side cross-sectional view of another embodiment of an integrated circuit package capable of independently assembling passive devices in accordance with the present invention.

As shown in FIGS. 8A and 8B, the integrated circuit package 70 includes two integrated circuits 701 and a heat dissipation structure 702. The two integrated circuits 701 are mounted on a circuit board 11.

The heat dissipation structure 702 is independently fabricated and includes a first-layer flat plate 7021 and a cavity 7022. The first-layer flat plate 7021 is disposed above the integrated circuits 701 and is in thermal contact with the top surfaces of the integrated circuits 701 via a thermal interface material (not shown in the drawings). In the present embodiment, the cavity 7022 is located on the upper side of the first-layer flat plate 7021 and has an opening for accommodating two passive devices 12. Both passive devices 12 may be inserted into or removed from the cavity 7022 via the opening to meet different application requirements.

An electrical conductor 121 of the passive device 12 extends externally from the side of the first-layer flat plate 7021 of the heat dissipation structure 702 and is connected to the circuit board 11 through a thermal conduction pillar 14 to complete the electrical connection. The electrical conductor 121 also ensures stable electrical performance between the passive device 12 and the circuit board 11.

The thermal conduction pillar 14 is disposed between the passive device 12 and the circuit board 11. It is formed of a metal having high thermal conductivity, such as copper, silver, gold, or aluminum. In addition to electrically and mechanically connecting the passive device 12 to the circuit board 11, the thermal conduction pillar 14 provides an additional thermal path from the integrated circuit 701 to the circuit board 11 and to the passive device 12 and the heat dissipation structure 702, thereby significantly improving heat dissipation efficiency. Moreover, the modular design of the thermal conduction pillar 14 allows adjustment of its quantity and layout according to the height requirements of different passive devices 12, offering a flexible solution for electrical, mechanical connection, and heat dissipation.

An electronic device 13 is mounted on the circuit board 11 and is electrically connected to the circuit board 11 through an electrical conductor 131.

As illustrated in FIGS. 8A and 8B, the heat dissipation structure 702 in this embodiment accommodates multiple passive devices 12. The top surfaces of the passive devices 12 are flush or substantially flush with the top surface of the heat dissipation structure 702, such that the passive devices 12 may simultaneously contact an external heat sink (not shown in the drawings), further enhancing the heat dissipation performance.

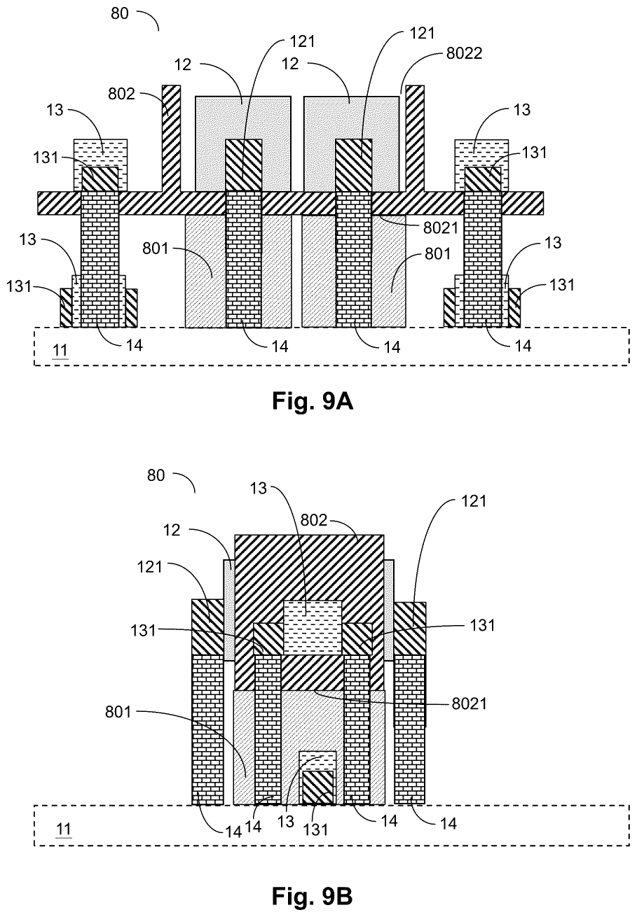

FIGS. 9A and 9B respectively illustrate a front cross-sectional view and a side cross-sectional view of another embodiment of an integrated circuit package capable of independently assembling passive devices in accordance with the present invention.

As shown in FIGS. 9A and 9B, the integrated circuit package 80 includes two integrated circuits 801 and a heat dissipation structure 802. The integrated circuits 801 are mounted on a circuit board 11.

The heat dissipation structure 802 includes a first-layer flat plate 8021 and a cavity 8022. The first-layer flat plate 8021 is thermally connected to the two integrated circuits 801 and further has two electronic devices 13 mounted thereon. The cavity 8022 is formed on the first-layer flat plate 8021 of the heat dissipation structure 802 and is configured to accommodate multiple passive devices 12. The cavity 8022 includes at least one opening, allowing insertion and removal of the passive devices 12.

An electrical conductor 121 of the passive device 12 extends externally from the side of the first-layer flat plate 8021 of the heat dissipation structure 802 and is connected to the circuit board 11 via a thermal conduction pillar 14 to complete the electrical connection. In addition, the electrical conductor 121 ensures stable electrical performance between the passive device 12 and the circuit board 11.

The thermal conduction pillar 14 is disposed between the passive device 12 and the circuit board 11 and is made of a high thermal conductivity metal, such as copper, silver, gold, or aluminum. The thermal conduction pillar 14 serves not only to electrically and mechanically connect the passive device 12 to the circuit board 11 but also to form an additional thermal conduction path from the integrated circuit 801 to the circuit board 11, the passive device 12, and the heat dissipation structure 802, thereby significantly enhancing thermal dissipation efficiency. Furthermore, the modular design of the thermal conduction pillar 14 enables adjustment of its quantity and layout according to the height requirements of different passive devices 12, providing a flexible solution for electrical and mechanical connection and heat dissipation.

The electronic device 13 is mounted on the circuit board 11, and its electrical conductor 131 is electrically connected to the circuit board 11.

Furthermore, the two electronic devices 13 on the first-layer flat plate 8021 have their electrical conductors 131 routed externally from the side of the first-layer flat plate 8021 of the heat dissipation structure 802 and connected to the thermal conduction pillars 14. The thermal conduction pillars 14 are electrically connected to the circuit board 11 and/or the electronic devices 13 disposed on the circuit board 11, thereby completing the electrical connection.

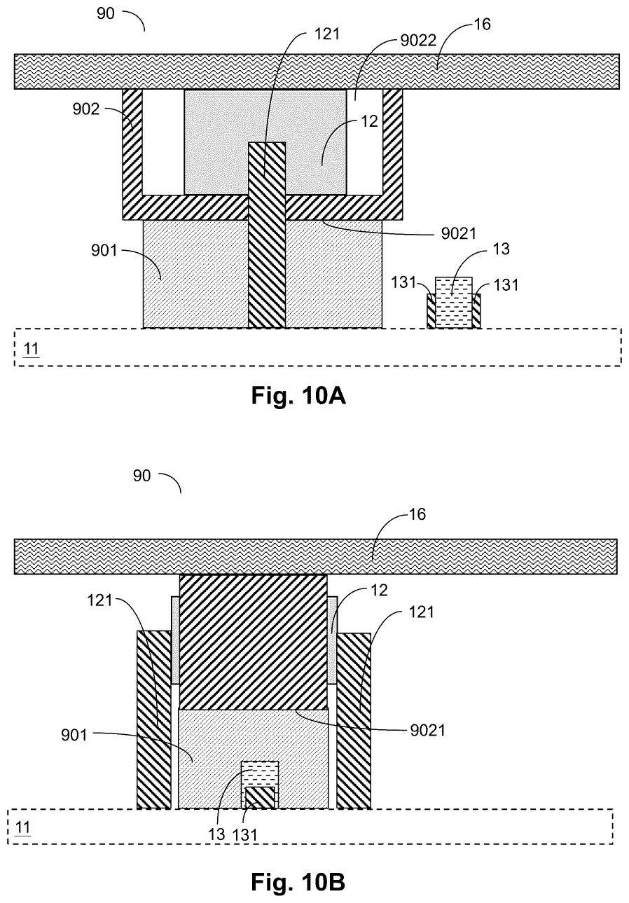

FIGS. 10A and 10B respectively illustrate a front cross-sectional view and a side cross-sectional view of another embodiment of an integrated circuit package 90 capable of independently assembling passive devices according to the present invention, along with its integration with a heat sink 16.

As shown in FIGS. 10A and 10B, the integrated circuit package 90 includes an integrated circuit 901 and a heat dissipation structure 902. The integrated circuit 901 is mounted on a circuit board 11. The heat dissipation structure 902 is independently manufactured and includes a first-layer flat plate 9021 and a cavity 9022. The first-layer flat plate 9021 is disposed above and in thermal contact with the integrated circuit 901. The cavity 9022 is located on one side of the first-layer flat plate 9021 and includes at least one opening for assembling a passive device 12.

An electrical conductor 121 of the passive device 12 is connected to the circuit board 11. Meanwhile, the top surface 921 of the passive device 12 is substantially flush with the top surface of the heat dissipation structure 902 and is in thermal contact with the heat sink 16, for example, via direct contact or through a thermal interface material. The heat sink 16 may be made of metal or other materials with high thermal conductivity and serves to rapidly dissipate the heat generated by the integrated circuit 901 and the passive device 12 to the external environment.

As shown in FIGS. 10A and 10B, the design of the heat dissipation structure 902 allows for the insertion and removal of the passive device 12. The cavity 9022 provides a flexible installation space suitable for passive devices 12 of various shapes or sizes. This design further enhances heat dissipation efficiency and improves the modularity and flexibility of the system.

In summary, FIGS. 10A and 10B demonstrate how the integrated circuit package 90 of the present invention, through its combination with the heat sink 16, can effectively transfer the heat generated by both the integrated circuit 901 and the passive device 12, thereby achieving optimal heat dissipation performance.

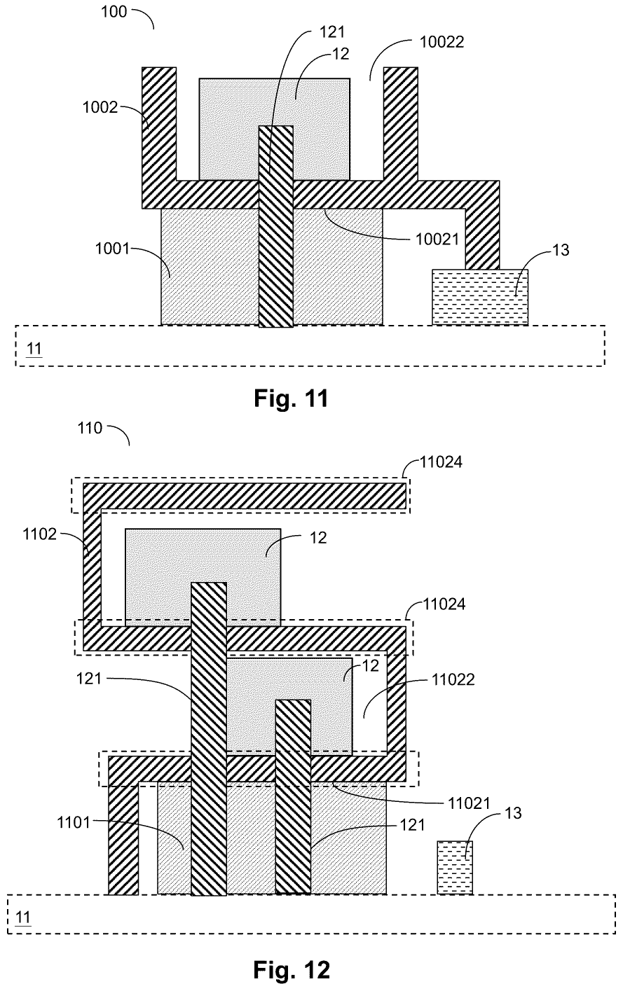

FIG. 11 illustrates a cross-sectional view of an integrated circuit package 100 capable of independently assembling passive devices according to the present invention. As shown in FIG. 11, the integrated circuit package 100 includes an integrated circuit 1001 and a heat dissipation structure 1002.

The integrated circuit 1001 is mounted on a circuit board 11. The heat dissipation structure 1002 is independently manufactured and includes a first-layer flat plate 10021 and a cavity 10022. The first-layer flat plate 10021 is disposed above the integrated circuit 1001 and is in thermal contact therewith. The cavity 10022 is located on one side of the first-layer flat plate 10021 and has at least one opening configured to accommodate a passive device 12.

During assembly, the passive device 12 is electrically connected to the circuit board 11 or the integrated circuit 1001 via its electrical conductor 121, and is removably mounted within the cavity 10022 of the heat dissipation structure 1002. This design enables flexible assembly of the passive device 12 and accommodates passive devices of various sizes or shapes.

The first-layer flat plate 10021 of the heat dissipation structure 1002 is thermally coupled to the top surface of the integrated circuit 1001, thereby effectively transferring the heat generated by the integrated circuit 1001 to the heat dissipation structure 1002 and further improving overall heat dissipation efficiency.

As shown in FIG. 11, the heat dissipation structure 1002 in this embodiment is designed with high flexibility. It not only supports independent assembly of the passive device 12 but also enhances the thermal performance of both the integrated circuit 1001 and the overall package system through its structural features. The heat dissipation structure 1002 can be thermally connected to an electronic component 13, further facilitating heat transfer—either from the heat dissipation structure 1002 to the electronic component 13 or vice versa. This design significantly enhances the modularity and applicability of the integrated circuit package 100, meeting the heat dissipation requirements of modern electronic devices.

FIG. 12 illustrates a cross-sectional view of an integrated circuit package 110 capable of independently assembling passive devices according to the present invention. As shown in FIG. 12, the integrated circuit package 110 includes an integrated circuit 1101 and a heat dissipation structure 1102.

The integrated circuit 1101 is mounted on a circuit board 11 and is used to support the operation of electronic components. The heat dissipation structure 1102 is independently manufactured and includes a first-layer flat plate 11021, a cavity 11022, and two second-layer flat plates 11024. The first-layer flat plate 11021 is disposed on the top surface of the integrated circuit 1101 and is in thermal contact with the integrated circuit 1101 to facilitate thermal conduction.

The cavity 11022 is located on one side of the first-layer flat plate 11021 and has at least one opening for accommodating a passive device 12. The passive device 12 is electrically connected to the circuit board 11 or the integrated circuit 1101 through its electrical conductor 121. During assembly, the passive device 12 may be inserted into the cavity 11022 through the opening of the heat dissipation structure 1102 and may optionally be removed from the cavity 11022. In a preferred embodiment, the cavity 11022 has three openings—specifically, when the cavity 11022 is considered a cuboid, three of its six outer surfaces are completely open prior to the installation of the passive device 12, thereby facilitating the placement of the passive device 12 into the cavity 11022.

In this embodiment, the heat dissipation structure 1102, in contrast to embodiments comprising only a first-layer flat plate 11021, further includes at least one second-layer flat plate 11024 (in this case, two second-layer flat plates 11024). This arrangement enables multiple passive devices 12 to be mounted in a stacked manner on the first-layer flat plate 11021 and the at least one second-layer flat plate 11024, thereby allowing the accommodation of a plurality of passive devices 12 or improving heat dissipation efficiency.

The heat dissipation structure 1102 is designed to enhance the heat dissipation performance of the integrated circuit 1101. Through thermal contact with the integrated circuit 1101, heat generated during its operation can be rapidly transferred to the heat dissipation structure 1102 and further dispersed to the external environment to reduce the operating temperature.

The features of this embodiment lie in the flexible assembly of the passive device 12 and the effective thermal conduction capability of the heat dissipation structure 1102. The modular and multilayered flat plate design of the heat dissipation structure 1102 can accommodate passive devices 12 of various sizes and quantities, thereby improving the assembly efficiency and flexibility of the integrated circuit package 110 and satisfying the high-performance heat dissipation requirements of modern electronic devices. In this embodiment, each passive device 12 is electrically connected to the circuit board 11 through its electrical conductor 121.

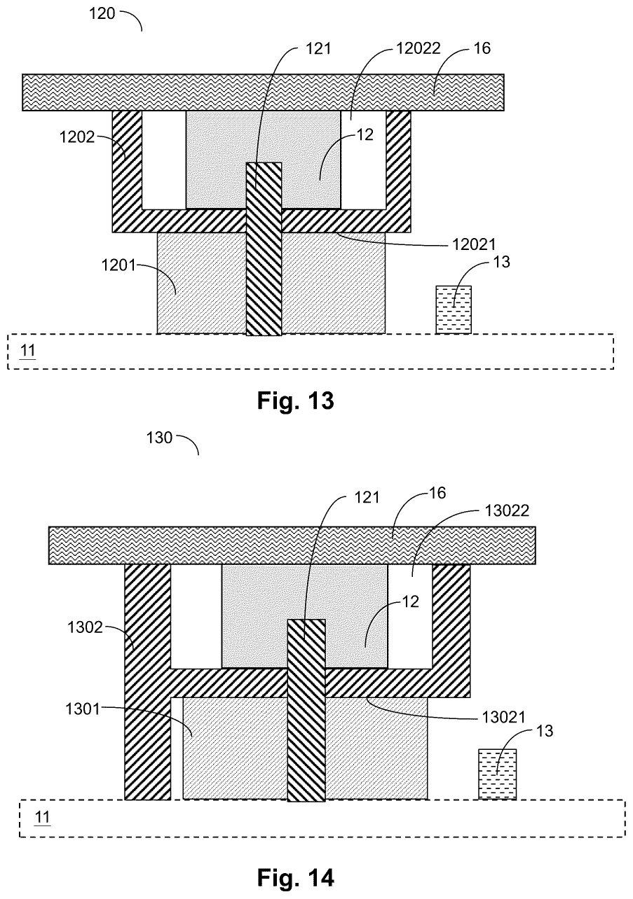

FIG. 13 illustrates a cross-sectional view of an integrated circuit package 120 capable of independently assembling passive devices according to the present invention. The integrated circuit package 120 includes an integrated circuit 1201 and a heat dissipation structure 1202.

The integrated circuit 1201 is mounted on a circuit board 11 and electrically connected thereto. The heat dissipation structure 1202 is independently manufactured and includes a first-layer flat plate 12021 and a cavity 12022. The first-layer flat plate 12021 is disposed on top of the integrated circuit 1201 and is in thermal contact with the integrated circuit 1201, thereby enabling effective heat conduction.

The cavity 12022 is located on one side of the first-layer flat plate 12021 and is formed with at least one opening suitable for accommodating a passive device 12. The passive device 12 is electrically connected to the circuit board 11 or the integrated circuit 1201 via its electrical conductor 121. During assembly, the passive device 12 may be inserted into the cavity 12022 through the opening of the heat dissipation structure 1202, and may optionally be removed from the cavity 12022.

Furthermore, the top surface of the heat dissipation structure 1202 is in contact with a heat sink 16, allowing the heat sink 16 to more effectively dissipate the heat generated by the integrated circuit 1201 during operation to the external environment. The upper surface of the passive device 12 is flush or substantially flush with the top surface of the heat dissipation structure 1202, so that the passive device 12 and the heat dissipation structure 1202 are simultaneously in contact with the external heat sink 16. This configuration improves overall heat dissipation efficiency and ensures that the integrated circuit 1201 operates stably at a lower temperature.

In this embodiment, the combination of the heat dissipation structure 1202 and the heat sink 16 provides a highly efficient thermal dissipation solution. Meanwhile, the modular design allows for rapid assembly and maintenance of the passive device 12, adapting to various application requirements and enhancing the flexibility and reliability of the integrated circuit package 120.

FIG. 14 illustrates a cross-sectional view of an integrated circuit package 130 capable of independently assembling passive devices according to the present invention. The integrated circuit package 130 includes an integrated circuit 1301 and a heat dissipation structure 1302.

The integrated circuit 1301 is mounted on a circuit board 11 and is electrically connected thereto via electrical conductors. The heat dissipation structure 1302 is independently manufactured and includes a first-layer flat plate 13021 and a cavity 13022. The first-layer flat plate 13021 is disposed on top of the integrated circuit 1301 and is in thermal contact with the integrated circuit 1301 to effectively conduct the heat generated thereby.

The cavity 13022 is located on one side of the first-layer flat plate 13021 and is formed with at least one opening configured to accommodate a passive device 12. The passive device 12 is electrically connected to the circuit board 11 or the integrated circuit 1301 via its electrical conductor 121. During the assembly process, the passive device 12 may be inserted into the cavity 13022 of the heat dissipation structure 1302 through the opening, and may optionally be detached from the cavity 13022 to facilitate maintenance and replacement.

Furthermore, the top surface of the heat dissipation structure 1302 is in contact with a heat sink 16, allowing the heat sink 16 to further dissipate the heat generated during the operation of the integrated circuit 1301 to the external environment. The upper surface of the passive device 12 is flush or substantially flush with the top surface of the heat dissipation structure 1302, enabling both the passive device 12 and the heat dissipation structure 1302 to simultaneously contact the external heat sink 16. This configuration enhances thermal dissipation efficiency and ensures that the integrated circuit 1301 operates stably at a suitable temperature.

In this embodiment, the integrated circuit package 130 features a modular design that provides efficient thermal management while simplifying the assembly and replacement of the passive device 12. This design is suitable for a variety of applications that require high heat dissipation efficiency and flexible component integration.

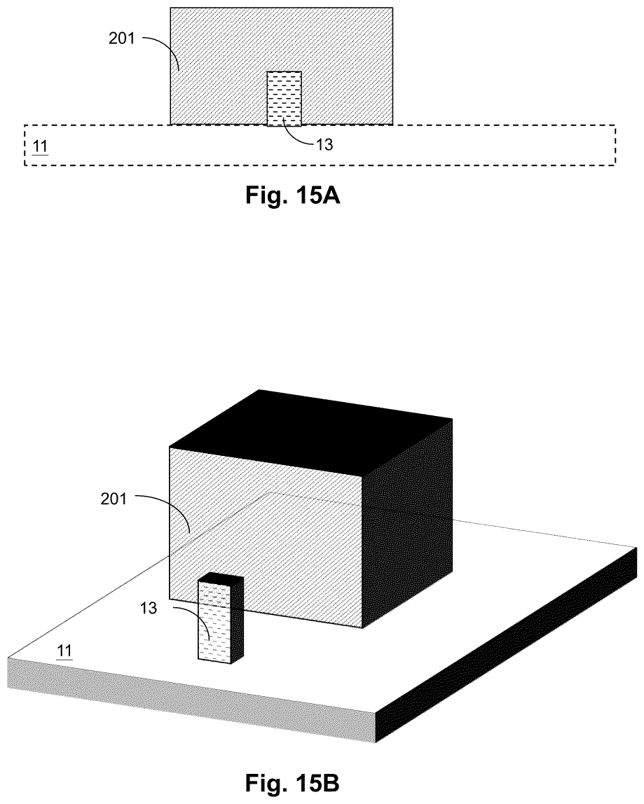

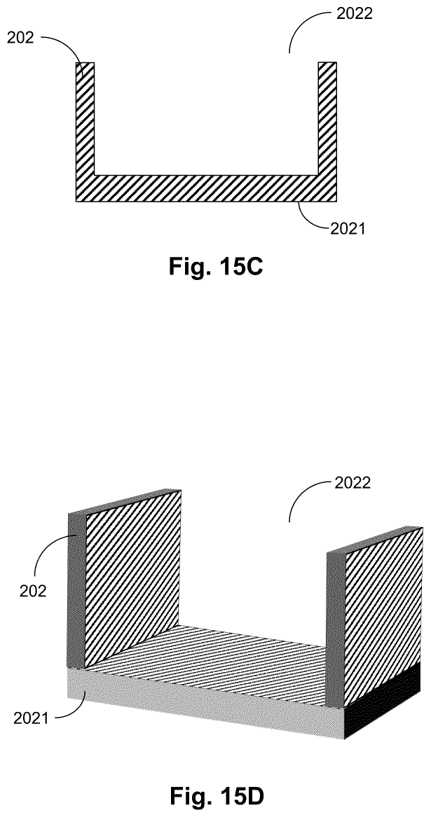

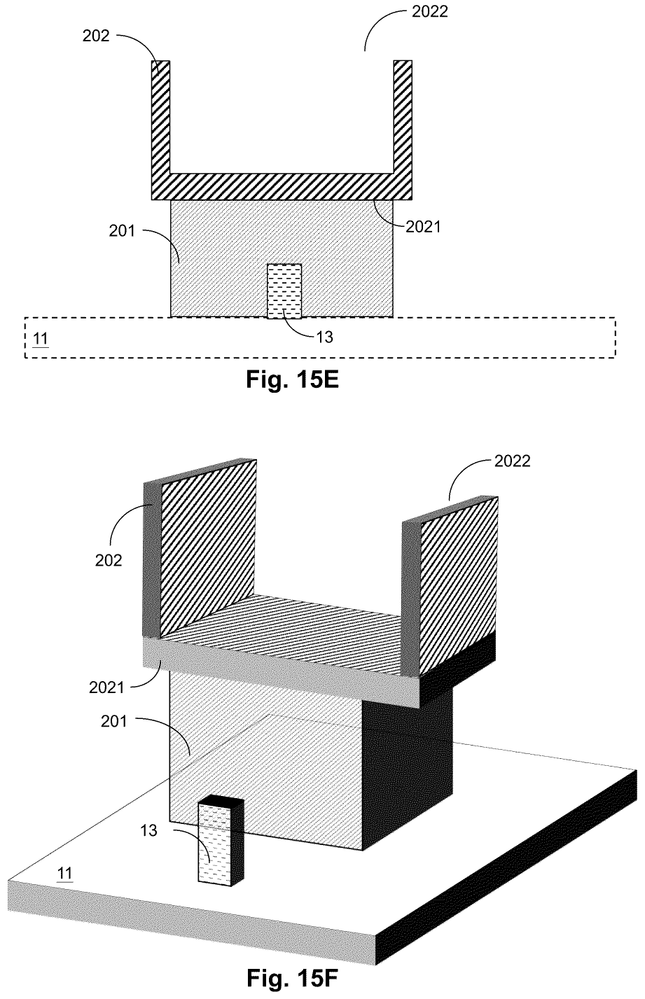

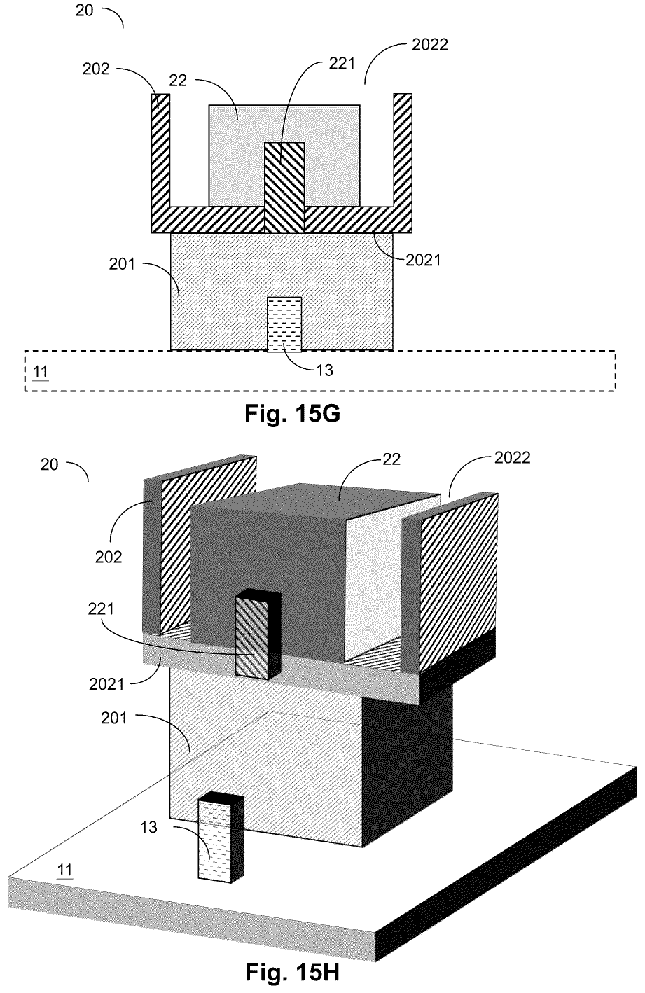

FIGS. 15A, 15C, 15E, and 15G are cross-sectional schematic diagrams illustrating different steps in the manufacturing process of an integrated circuit package 20 capable of independently assembling passive devices according to the present invention. FIGS. 15B, 15D, 15F, and 15H are corresponding perspective schematic diagrams for FIGS. 15A, 15C, 15E, and 15G, respectively.

As shown in FIGS. 15A and 15B, an integrated circuit 201 and an electronic component 13 are first provided. The integrated circuit 201 and the electronic component 13 are both mounted on a circuit board 11. The electronic component 13 may optionally include electrical conductors 131 (not shown), which are adapted to be electrically connected to the circuit board 11.

As shown in FIGS. 15C and 15D, a heat dissipation structure 202 is independently manufactured, which includes a first-layer flat plate 2021 and a cavity 2022. The material of the heat dissipation structure 202 may be selected from metal materials, such as aluminum, copper, or aluminum nitride, or non-metallic materials, such as aluminum nitride, silicon carbide, or graphite. The manufacturing process may include, for example, casting, milling, turning, stamping, or forging.

As shown in FIGS. 15E and 15F, the heat dissipation structure 202 is mounted on top of the integrated circuit 201. The first-layer flat plate 2021 is thermally contacted with the top surface of the integrated circuit 201 to facilitate the transfer of heat generated by the integrated circuit 201.

As shown in FIGS. 15G and 15H, a passive device 22 (e.g., an inductor) is inserted into the cavity 2022 of the heat dissipation structure 202. This step is performed through an opening of the heat dissipation structure 202. The electrical conductor 221 of the passive device 22 is electrically connected to the circuit board 11 or the integrated circuit 201.

A thermal interface material may be applied between the first-layer flat plate 2021 of the heat dissipation structure 202 and the top surface of the integrated circuit 201 to further enhance thermal dissipation performance. After the structure 20 is fully assembled, an external heat sink may optionally be attached.

The above descriptions illustrate implementation details of the integrated circuit package and its manufacturing method. Each step and material selection may be adjusted according to specific requirements in order to achieve optimal thermal dissipation and electrical connectivity performance.

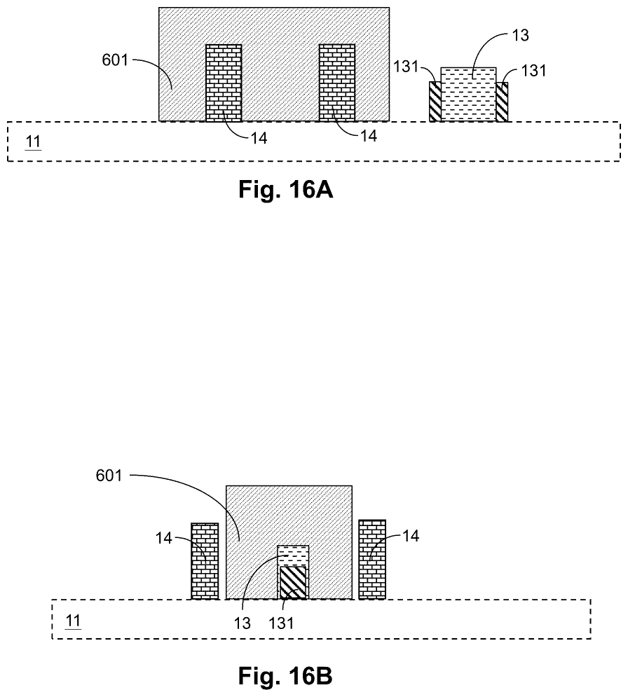

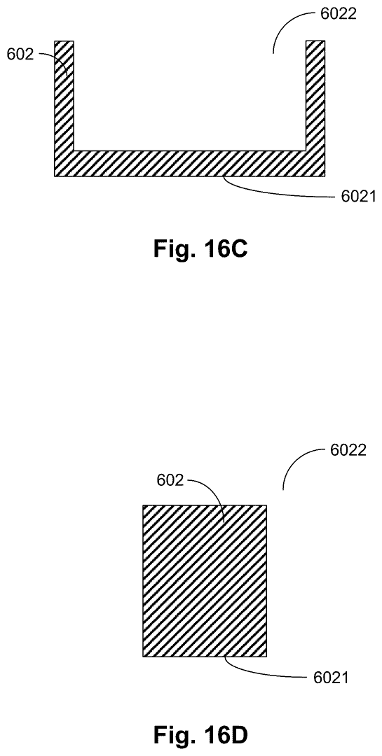

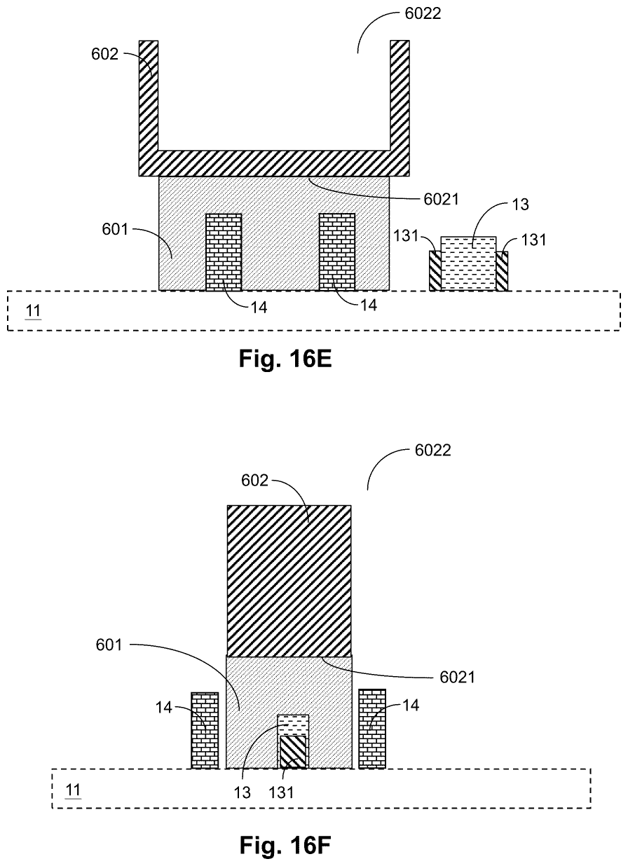

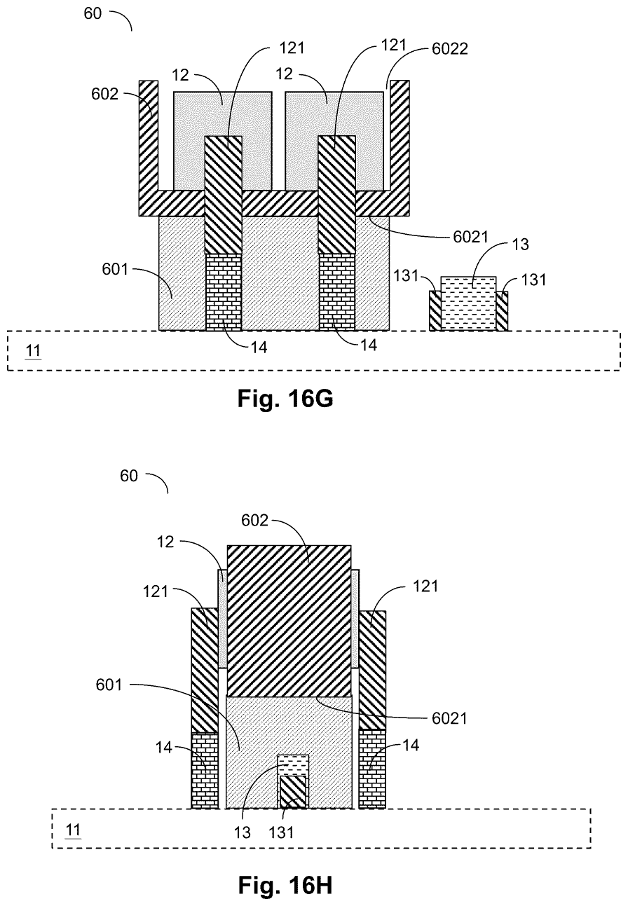

FIGS. 16A to 16H are schematic cross-sectional views illustrating different steps in the manufacturing process of an integrated circuit package 60 capable of independently assembling passive devices according to the present invention. FIGS. 16B, 16D, 16F, and 16H are side cross-sectional views corresponding to the front cross-sectional views of FIGS. 16A, 16C, 16E, and 16G, respectively. This embodiment provides a method of manufacturing the integrated circuit package 60.

First, as shown in FIGS. 16A and 16B, an integrated circuit 601 is provided and mounted on a circuit board 11. The integrated circuit 601 includes two thermal conduction pillars 14, which are used in subsequent assembly steps for connection with passive devices 12. An electronic component 13 is also disposed on the circuit board 11. The electronic component 13 includes two electrical conductors 131 for electrically connecting the electronic component 13 to the circuit board 11.

Next, as shown in FIGS. 16C and 16D, a heat dissipation structure 602 is independently manufactured. The heat dissipation structure 602 includes a first-layer flat plate 6021 and a cavity 6022. The first-layer flat plate 6021 is disposed at the bottom of the heat dissipation structure 602 and is configured to contact the integrated circuit 601. The cavity 6022 is located above the first-layer flat plate and includes at least one opening.

As shown in FIGS. 16E and 16F, the heat dissipation structure 602 is assembled above the integrated circuit 601, so that the first-layer flat plate 6021 of the heat dissipation structure 602 is in thermal contact with the top surface of the integrated circuit 601. At this stage, the electronic component 13 remains electrically connected to the circuit board 11.

Finally, as shown in FIGS. 16G and 16H, two passive devices 12 are inserted into the cavity 6022 of the heat dissipation structure 602 and connected to the thermal conduction pillars 14 through their respective electrical conductors 121, thereby completing the electrical connection between the passive devices 12 and the circuit board 11.

This manufacturing method effectively enhances the thermal dissipation efficiency of the integrated circuit package and enables flexible assembly of the passive devices.

The above description has explained the invention with reference to specific embodiments. However, these descriptions are merely intended to facilitate understanding by those skilled in the art and are not meant to limit the scope of the invention. Under the same inventive spirit, those skilled in the art may contemplate various equivalent modifications. For example, the cavity may accommodate a different number of passive devices from those shown in the figures, or the circuit board may include a different number of electronic components or integrated circuits than illustrated. The scope of the present invention should cover all such equivalent variations.

What is claimed is:

1. An integrated circuit package capable of independently assembling a passive device, comprising:
an integrated circuit configured to be mounted on a circuit board; and
a heat dissipation structure, which is manufactured independently and comprises:
a first-layer flat plate disposed above the integrated circuit and in thermal contact with the integrated circuit; and
a cavity located at one side of the first-layer flat plate, the cavity having at least one opening to accommodate a passive device;
wherein the passive device is assembled into the cavity through the at least one opening of the heat dissipation structure and is electrically connected to the circuit board or the integrated circuit through an electrical conductor of the passive device;
wherein heat generated by the integrated circuit is transferred through the heat dissipation structure.

2. The integrated circuit package of claim 1, wherein the passive device comprises an inductor.

3. The integrated circuit package of claim 1, wherein the heat dissipation structure is made of a formable metal comprising steel, copper, silver, gold, aluminum, tungsten, zinc, or stainless steel.

4. The integrated circuit package of claim 3, wherein the heat dissipation structure is formed by a process selected from casting, milling, turning, stamping, or forging.

5. The integrated circuit package of claim 1, wherein the heat dissipation structure is made of a non-metal material comprising aluminum nitride, silicon carbide, or graphite.

6. The integrated circuit package of claim 1, wherein the first-layer flat plate is attached to a top surface of the integrated circuit via a thermal interface material.

7. The integrated circuit package of claim 1, wherein the passive device is optionally inserted into or removed from the cavity through the at least one opening.

8. The integrated circuit package of claim 1, wherein a top surface of the passive device is flush or substantially flush with a top surface of the heat dissipation structure such that the passive device and the heat dissipation structure simultaneously contact an external heat sink.

9. The integrated circuit package of claim 1, wherein the heat dissipation structure further comprises at least one second-layer flat plate, and a plurality of the passive devices are disposed in a stacked manner on the first-layer flat plate and the at least one second-layer flat plate, to accommodate multiple passive devices or to enhance heat dissipation efficiency.

10. The integrated circuit package of claim 1, wherein the passive device is further connected to the circuit board through a thermal conduction pillar, the thermal conduction pillar being made of a formable metal comprising copper, silver, gold, or aluminum.

11. A method of manufacturing an integrated circuit package capable of independently assembling a passive device, comprising:
mounting an integrated circuit on a circuit board;
independently pre-fabricating a heat dissipation structure, the heat dissipation structure comprising a first-layer flat plate and a cavity, the cavity being located at one side of the first-layer flat plate and having at least one opening;
mounting the heat dissipation structure above the integrated circuit such that the first-layer flat plate is in thermal contact with the integrated circuit; and
inserting at least one passive device into the cavity through the at least one opening, and electrically connecting the passive device to the circuit board or the integrated circuit via an electrical conductor of the passive device.

12. The method of claim 11, wherein the passive device comprises an inductor.

13. The method of claim 11, wherein the heat dissipation structure is made of a formable metal comprising steel, copper, silver, gold, aluminum, tungsten, zinc, or stainless steel.

14. The method of claim 13, wherein the heat dissipation structure is formed by a process selected from casting, milling, turning, stamping, or forging.

15. The method of claim 11, wherein the heat dissipation structure is made of a non-metal material comprising aluminum nitride, silicon carbide, or graphite.

16. The method of claim 11, wherein the first-layer flat plate is attached to a top surface of the integrated circuit via a thermal interface material.

17. The method of claim 11, wherein the passive device is optionally inserted into or removed from the cavity through the at least one opening.

18. The method of claim 11, wherein a top surface of the passive device is flush or substantially flush with a top surface of the heat dissipation structure such that the passive device and the heat dissipation structure simultaneously contact an external heat sink.

19. The method of claim 11, wherein the heat dissipation structure further comprises at least one second-layer flat plate, and a plurality of the passive devices are disposed in a stacked manner on the first-layer flat plate and the at least one second-layer flat plate, to accommodate multiple passive devices or to enhance heat dissipation efficiency.

20. The method of claim 11, wherein the passive device is further connected to the circuit board through a thermal conduction pillar, the thermal conduction pillar being made of a formable metal comprising copper, silver, gold, or aluminum.
